(19) United States
(12) Patent Application Publication
(10) Pub. No.: US 2009/0268461 A1
(43) Pub. Date: Oct. 29, 2009

(54) Photon energy conversion structure

(76) Inventors: David G. Deak, Brooklyn, NY (US); Joseph Lam, Chai Wan (HK)

Correspondence Address: LUCAS & MERCANTI, LLP, 475 PARK AVENUE SOUTH, 15TH FLOOR, NEW YORK, NY, 10016, US

(21) Appl. No.: 12/150,528

(22) Filed: Apr. 28, 2008

(51) Int. Cl. F21V 7/00; H01L 33/00; H01J 1/62

(52) U.S. Cl. 362/247; 257/98; 313/503; 257/E33.001

(57) ABSTRACT

A photon energy conversion device uses at least one ultraviolet light emitting diode (UV-LED) with a wavelength shifting medium such as phosphor or quantum dots. The device can be used as a light source, and shaped like incandescent light bulbs, fluorescent tubes, circles or compact fluorescent bulbs.

### BACKGROUND OF THE INVENTION

The present invention relates to structures using ultraviolet light emitting diodes (UV-LEDs), one example being a highly efficient solid state lighting source based on UV-LED and phosphor combinations. Such a structure can provide an UV-LED energy efficient light source for exact replacement of conventional incandescent light bulbs and fluorescent lighting systems.

Another aspect of the invention is a solar panel which produces electrical energy in response to incoming photons.

The invention also provides methods for improving the phosphor coating conversion efficiency in UV-LEDs, where the fundamental quenching mechanisms for phosphor coatings can be determined and quantified.

For more than 100 years incandescent light bulbs have been using for providing light in homes, businesses and other structures. One recognized problem with incandescent bulbs is that they are a very inefficient light source because most of the electrical energy applied to the incandescent light bulb is lost in heat instead of creating light. Not only is this a waste of energy, but when used in locations where heat is not desired, such as in warm environments, additional power is consumed by AC systems to remove the additional heat resulting in more inefficiencies and waste.

A standard tungsten incandescent light bulb emits a very broad spectrum of light. If you took all the light wavelengths into consideration, including all those that were invisible to the human eye, the light bulb's electrical power to light power conversion efficiency would approach 100%. However, much of the light emitted from such a source takes the form of long infrared heat wavelengths. Although still considered light, heat wavelengths fall well outside the response curve of both our human eye and a silicon detector. If you only considered the visible portion of the spectrum, the light bulb's efficiency would only be about 10%. But, to a detector that was sensitive to heat wavelengths, the bulb's efficiency would appear to be closer to 90%. This takes us to one of the most confusing areas of science, which is how one defines the brightness or intensity of a light source.

It isn't enough to say that a standard 100 watt bulb emits more light than a tiny 1 watt bulb. Sure, if one would place a big 100 watt bulb next to a small 1 watt flashlight bulb, the 100 watt bulb would appear to emit more light. But there are many factors to consider when defining the brightness of a light source. Some factors refer to the nature of the emitted light and others to the nature of the detector being used to measure the light. For some light emitting devices, such as a standard tungsten incandescent light bulb, the light is projected outward in all directions (omni-directional). When visually compared to a bare 1 watt bulb, the light emitted from a bare 100 watt bulb would always appear brighter. However, if you were to position the tiny 1 watt bulb in front of a mirror, like a flashlight reflector, the light emerging from the 1 watt light assembly would appear much brighter than the bare 100 watt, if viewed at a distance of perhaps 100 feet. So, the way the light is projected outward from the source can influence the apparent brightness of the source. An extreme example of a highly directional light source is a laser. Some lasers, including many common visible red laser pointers, are so directional that the light beams launched spread out very little. The bright spot of light emitted might remain small even after traveling several hundred feet. The preferential treatment that a detector gives to some light wavelengths, over others, can also make some sources appear to be brighter than others. As an example, suppose you used a silicon light detector and compared the light from a 100 watt black-light lamp that emits invisible ultraviolet light, with a 100 watt tungsten bulb. At a distance of a few feet, the silicon detector would indicate a sizable amount of light being emitted from the light bulb but would detect very little from the black-light source, even though the ultraviolet light could cause skin burns within minutes.

In order to define how much light a source emits you first need to specify what wavelengths you wish to be considered. You must also assign a certain value to each of the considered wavelengths, based on the detector being used. In addition, since many light sources launch light in all directions you must also define the geometry of how the light is to be measured. Perhaps you only want to consider the amount of light that can be detected at some distance away. The wavelengths you may want to consider will depend on the instrument used to make the measurements. If the instrument is the human eye then you need to consider the visible wavelengths and you will need to weigh each of the wavelengths according to the human eye sensitivity curve. If the instrument were a silicon detector, then you would use its response curve.

Many different units for light and illumination are being used by various light manufacturers. While all the units are trying to describe how much light a device emits, one will see units such as candle power, foot candles, candelas, foot lamberts, lux, lumens and my favorite: watts per steradian. Some units refer to the energy of the light source and others to the power. Many units take only the human eye sensitivity into account. The light units can be even more confusing when you consider that some light sources, such as a common light bulb, launch light in all directions while others, such as a laser, concentrate the light into narrow beams.

Let's just assume that each light source has a distinctive emission spectrum and a certain emission geometry. One will have to treat each light source differently, according to how it is used with a specific communications system. In optical communications you only need to consider the light that is sent in the direction of the detector. One also only need to consider the light that falls within the response curve of the detector you use. One should regard all the rest of the light as lost and useless. Since all the light sources rely on electricity to produce light, each source will have an approximate electrical power (watts) to optical power (watts) conversion efficiency, as seen by a silicon detector. One can use the approximate power efficiency and the known geometry of the emitted light to calculate how much light will be emitted, sent in the direction of the light detector and actually collected.

The scientific unit for power is the “watt”. Since the intensity of a light source can also be described as light power, the watt is perhaps the best unit to use to define light intensity.

However, power should not be confused with energy. Energy is power multiplied by time. The longer a light source remains turned on, the more energy it transmits. But all of the light detectors are energy independent. They convert light power into electrical power in much the same way as a light source might convert electrical power into light power. The conversion is independent of time. This is a very important concept and is paramount to some of the circuits used for communications.

To help illustrate how this effects light detection, imagine two light sources. Let us say that one source emits one watt of light for one second while the other launches a million watts for only one millionth of a second. In both cases the same amount of light energy is launched. However, because light detectors are sensitive to light power, the shorter light pulse will appear to be one million times brighter and will therefore be easier to detect. This peak power sensitivity concept of light processing is a very important concept and is often neglected in many optical communications systems.

The watt is more convenient to use since light detectors, used to convert the light energy into electrical energy, produce an electrical current proportional to the light power, not its energy. Detectors often have conversion factors listed in amps per watt of light shining on the detector.

In sum, when evaluating light sources and their efficiency to produce light or illumination, one should be cognizant of the spatial region over which the light energy is being produced, as well as the frequency range or wavelength over which the light energy is being produced.

With the keen interest in reversing global warming and conserving energy consumption, many countries throughout the world, or parts of countries, have enacted or proposed legislation to ban the further sale of incandescent lights. Reports of such regions include Europe, Australia and California.

One replacement for incandescent light bulbs has been fluorescent light bulbs. For more than 60 years, fluorescent lighting has been used in offices and homes as a low-cost, energy-saving power source.

Two essential elements are involved in fluorescent lighting are plasma and phosphors. In a fluorescent tube, electrical energy is used to excite electrons in conducting plasma, which emits ultraviolet photons that then strike a phosphorescent layer on the inner surface of the tube, emitting visible light. Mercury is used in plasma because it converts electrical energy into relatively low-energy ultraviolet photons with a high level of efficiency.

Fluorescent lamps work on the principle of “fluorescence” and because of their low cost have many through-the-air applications. An electrical current passed through a mercury vapor inside a glass tube causes the gas discharge to emit ultraviolet “UV” light. The UV light causes a mixture of phosphors, painted on the inside wall of the tube, to glow at a number of visible light wavelengths. The electrical to optical conversion efficiency of these light sources is fairly good, with about 3 watts of electricity required to produce about 1 watt of light. A cathode electrode at each end of the lamp that is heated by the discharge current, aids in maintaining the discharge efficiency, by providing rich electron sources. By turning on and off the electrical discharge current, the light being emitted by the phosphor, can be modulated. Also, by driving the tubes with higher than normal currents and at low duty cycles, a fluorescent lamp can be forced to produce powerful light pulses. However, the fluorescent lamp pulsing techniques must use short pulse widths to avoid destruction of the lamp.

To modulate a fluorescent lamp to transmit useful information, the negative resistance characteristic of the mercury vapor discharge within the lamp must be dealt with. This requires the drive circuit to limit the current through the tube. The two heated cathode electrodes of most lamps also require the use of alternating polarity current pulses to avoid premature tube darkening. The typical household fluorescent lighting uses an inductive ballast method to limit the lamp current. Although such a method is efficient, the inductive current limiting scheme slows the rise and fall times of the discharge current through the tube and thus produces longer then desired light pulses. To achieve a short light pulse emission, a resistive current limiting scheme seems to work better. In addition, there seems to be a relationship between tube length and the maximum modulation rate. Long tubes do not respond as fast as shorter tubes. As an example, a typical 48″ 40 watt lamp can be modulated up to about 10,000 pulses per second, but some miniature 2″ tubes can be driven up to 200,000 pulses per second. The main factor that ultimately limits the modulation speed is the response time of the phosphor used inside the lamp. Most visible phosphors will not allow pulsing much faster than about 500,000 pulses per second. The visible light emitted by the typical “cool white” lamp is also not ideal when used with a silicon photo diode. However, some special infrared light emitting phosphors could be used to increase the relative power output from a fluorescent lamp, which may also produce faster response times.

If a conventional “cool white” lamp is used, a 2:1 power penalty will be paid due to the broad spectrum of visible light being emitted. This results since the visible light does not appear as bright to a silicon light detector as IR light (see section on light detectors). Also, light detectors with built-in visible filters should not be used, since they would not be sensitive to the large amount of visible light emitted by the lamps. Although the average fluorescent lamp is not an ideal light source, the relative low cost and the large emitting surface area make it ideal for communications applications requiring light to be broadcasted over a wide area. Experiments indicate that about 20 watts of light can be launched from some small 9-watt lamps at voice frequency pulse rates (10,000/sec). Such power levels would require about 100 IR LEDs to duplicate. But, the large surface emitting areas of fluorescent lamps makes them impractical for long-range applications, since the light could not be easily collected and directed into a tight beam.

Fluorescent bulbs last longer, are more energy efficient than incandescent bulbs, and have reduced the load on power plants. More recently, compact fluorescent lights (CFLs) have become widely adopted. They are typically in the shape of a wound spiral, and many people have been reluctant to use them because they believe their shape is not esthetically pleasing. Also, another downside is that fluorescent tubes contain toxic mercury vapor. In the early 1990s, it has been reported that it cost $275 million annually to dispose of fluorescent tubes in an environmentally sound manner, greatly burdening the industry and its end users. In fact, during this period, several states enacted legislation to ban or limit the disposal of any products containing mercury.

Humans with their spectrum of vision perceive different visual stimuli as the color “white”. Not only broad band emissions from daylight sources produce a “white” perception, but also narrow band light sources like fluorescent tubes. These are glass tubes filled with mercury vapor and electrodes at each end. The interior of the tube is coated with a fluorescent material consisting of a phosphor. This material absorbs most of the UV—part of the mercury emission and show broad band luminescence mainly in the red part of the visible spectrum. The white light produced in fluorescent tubes is a combination of the visible emission of mercury at 368, 408 and 439 nm and the broad luminescence of the coating which is mainly in the red part of the spectrum. In recent years, there is a growing concern about the mercury which eventually pollutes the environment because it is a health hazard. Therefore, there is an increasing demand for light emitting devices that can be operated without mercury.

When an average human eye responds to various amounts of ambient light, a shift in sensitivity occurs because two types of photoreceptors called cones and rods are responsible for the eye's response to light. The eye's response under normal lighting conditions is called the photopic response. The cones respond to light under these conditions.

Cones are composed of three different photo pigments that enable color perception. The response peaks at 555 nanometers, which means that under normal lighting conditions, the eye is most sensitive to a yellowish-green color. When the light level drops to near total darkness, the response of the eye changes significantly as shown by the scotopic response curve on the left. At this level of light, the rods are most active and the human eye is more sensitive to the light present, and less sensitive to the range of color. Rods are highly sensitive to light but are comprised of a single photo pigment, which accounts for the loss in ability to discriminate color. At this very low light level, sensitivity to blue, violet, and ultraviolet is increased, but sensitivity to yellow and red is reduced. The eye's response at the ambient light level found in a typical inspection booth peaks at 550 nanometers, which means the eye is most sensitive to yellowish-green color at this light level. Fluorescent penetrant inspection materials are designed to fluoresce at around 550 nanometers to produce optimal sensitivity under dim lighting conditions. Robinson, S. J. and Schmidt, J. T., “Fluorescent Penetrant Sensitivity and Removability—What the Eye Can See,” a Fluorometer Can Measure, Materials Evaluation, Vol. 42, No. 8, July 1984, pp. 1029-1034.

With the aid of a glass prism one can demonstrate that the white light coming from the sun is actually made up of many different colors. Some of the light falls into the visible portion of the spectrum while wavelengths, such as the infrared and ultraviolet rays, remain invisible. The spectrum that lies just outside the human eye red sensitivity limit is called “near infrared” or simply IR. It is this portion of the spectrum that is used by much of today's light-beam communications systems. Sunlight is a very powerful source for this band of light, so are standard incandescent lamps and light from camera photo-flash sources. However, many other man-made light emitters, such as fluorescent lamps and the yellow or blue/white street lamps, emit very little infrared light.

One light source that has been proposed and used to some extent to replace both incandescent and fluorescent lighting is LED lighting. At first LEDs were made in colors, the primary on being red. Of course, colored LEDs are not generally acceptable as a light source to replace white light incandescent and fluorescent lighting. Attempts have been made to produce LEDs to emit white light.

There are currently two methods commonly used for LED-based white light generation: (1) individual red-green-blue (RGB) LED combinations that mix to generate white light, and (2) InₓGa₁₋ₓN-based blue and near-UV (NUV; 380 to 410 nm) LED systems incorporating fluorescent phosphors that down-convert some of the emission to generate a mix of light. The RGB approach requires at least three LEDs, and each device must be adjusted by individual supply circuits to balance the emission intensity of each color for proper white light generation.

Several problems currently exist with white-light devices composed of blue LEDs and Ce³⁺-doped yttrium aluminum garnet (Ce:YAG) yellow phosphors that mix blue and yellow light to produce what appears to be white light. These include the halo effect of blue/yellow color separation, strong temperature and current dependence of chromaticity, and poor color rendering caused by the lack of green and red components.

A lighting source requires high-quality light radiation because when we look at objects, we see the reflected light. The spectrum of the illumination source affects the appearance of objects in a phenomenon we call color rendering. If the illumination source does not include a spectrum close to that of incandescent bulbs or the sun, then the color of objects will be different than what we are accustomed to and there will be reluctance to use a light source which has a different color rendering that people are accustomed to.

There is a need for a light source which is highly efficient in producing light energy and which also produces acceptable color rendering. When considering efficiency, one should consider the spatial region over which the light energy is being produced and whether that meets the user's needs, and also over what frequency range or spectrum the light energy is being produced and whether that meets the user's needs, especially from a color rendering standpoint.

### SUMMARY OF THE INVENTION

An objective of the invention is to contribute to the reduction of greenhouse gases by reducing the amount of energy spent on artificial illumination.

The present invention provides an improvement over prior art lights with improved light output per energy consumed, color temperatures that simulate the color range of incandescent light, Halogen lights, and the general classification of all fluorescent lights that includes the novel “low wattage” fluorescent bulb replacements for the incandescent light bulb.

The present invention provides a replacement for incandescent and Halogen bulbs as well as certain types of neon lighting components.

Light sources according to the present invention reduce the power, efficiency, complexity, cost, and compromise to the greenhouse effect by using ultraviolet light emitting diodes as opposed to fluorescent light, incandescent light, and Halogen light.

An object of the invention is to provide an LED light source which provides high luminous efficiency with high color rendering. According to the invention, this can be accomplished by matching an appropriate multicolor phosphor and encapsulation material to the near ultraviolet (NUV) region, to obtain white LEDs with both high color rendering and high luminous efficacy. The high efficiency of white-light LEDs means that the active potential exists for enormous energy savings.

### BRIEF DESCRIPTION OF THE DRAWING

FIG. 1 is a side elevational view of a light source according to the invention;

FIG. 2 is a top plan view in cross-section of the light source of FIG. 1, showing the UV-LED array;

FIG. 3 is a plan view of a staggered wavelength UV-LED array;

FIG. 4 shows a single linear UV-LED array;

FIG. 5 shows multi-arrayed UV-LEDs;

FIG. 6 shows UV-LEDs mounted in a disk array;

FIG. 7 shows UV-LEDs arranged in a tubular array;

FIG. 8 shows an octagonal UV-LED array, in plan and perspective side view;

FIG. 9 shows a UV-LED light in the size and shape of a fluorescent tube;

FIG. 10 shows UV-LEDs in a horizontal circular array;

FIG. 11 shows UV-LEDs in a series circular array;

FIG. 12 shows an elevated view in cross section of a different embodiment of a light source from that of FIG. 1;

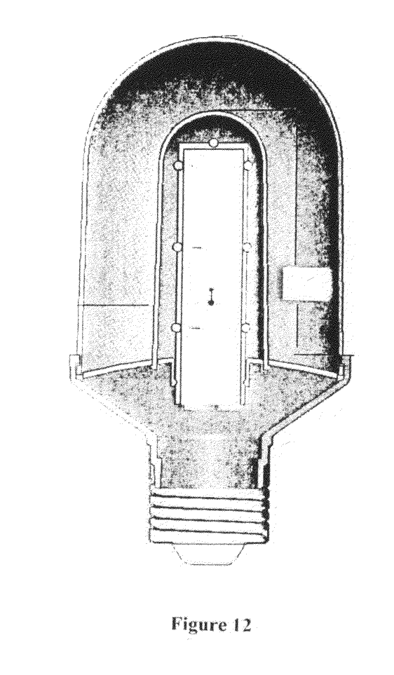

FIG. 13 shows a perspective view of the embodiment of FIG. 12;

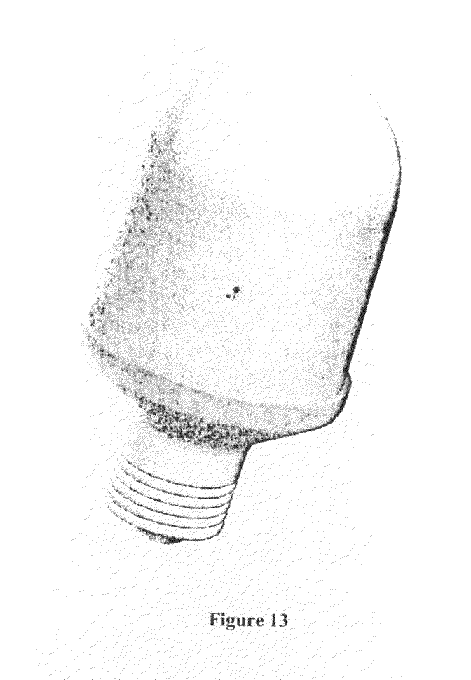

FIG. 14 shows portions of the embodiment of FIG. 12;

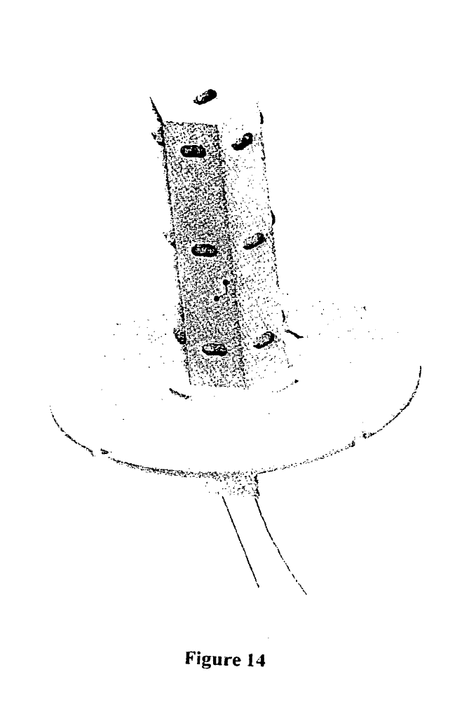

FIG. 15 shows the underside of the portion of FIG. 14;

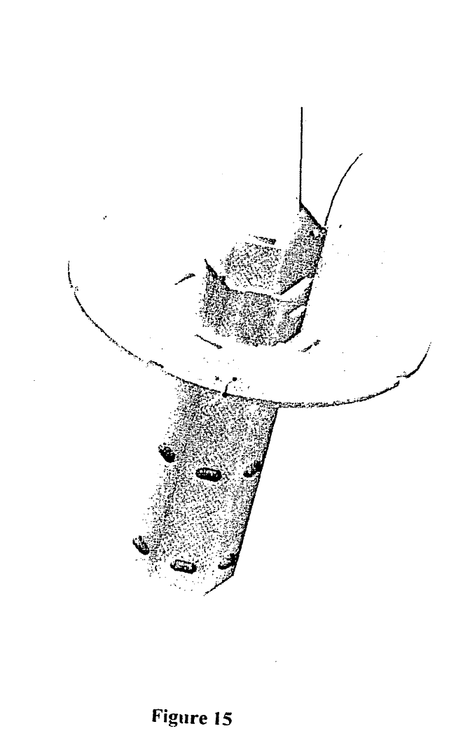

FIG. 16 shows portions of the embodiment of FIGS. 12-15;

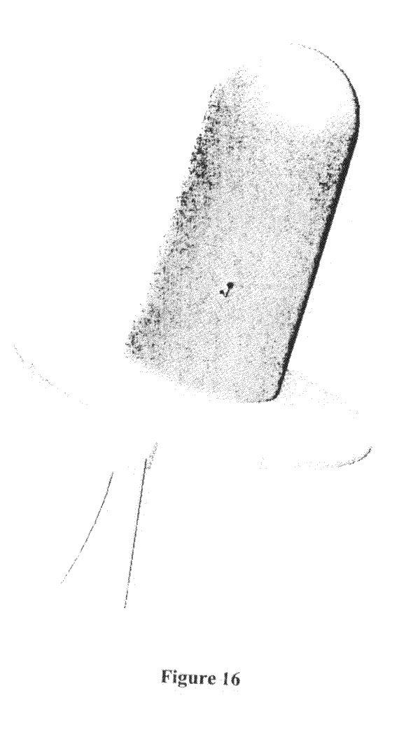

FIG. 17 shows the embodiment of FIGS. 12-16;

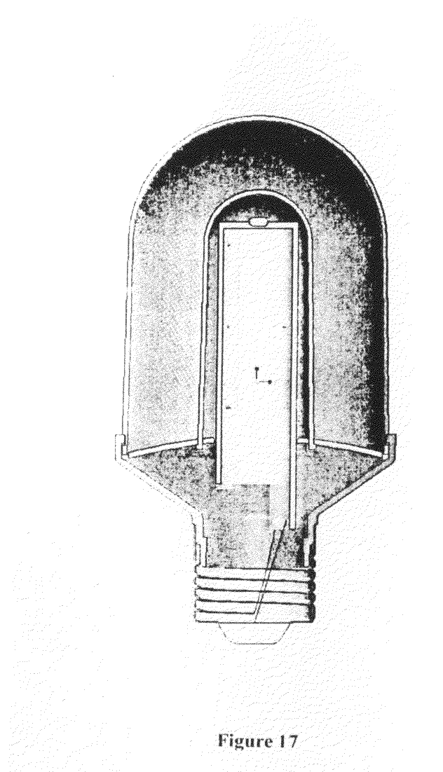

FIG. 18 shows the embodiment of FIGS. 12-17, without the dome;

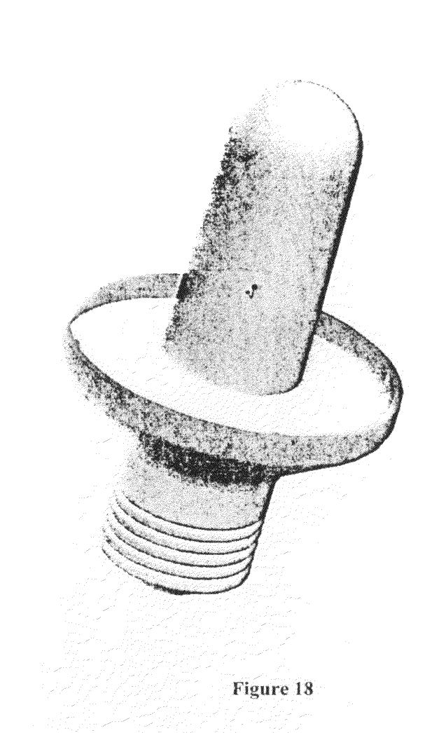

FIG. 19 shows another embodiment with multiple LEDs arranged on a hexagonal shaped center post; and

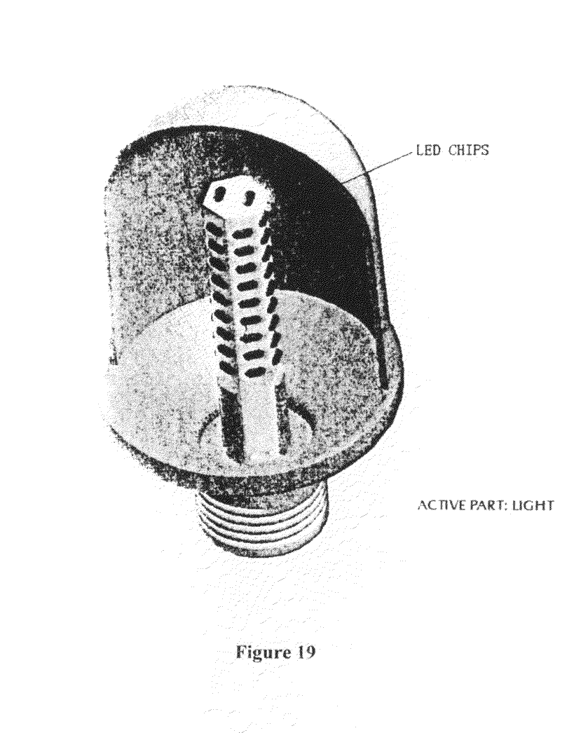

FIG. 20 shows the same embodiment of FIG. 19, in elevated view in cross section, but with the reflector.

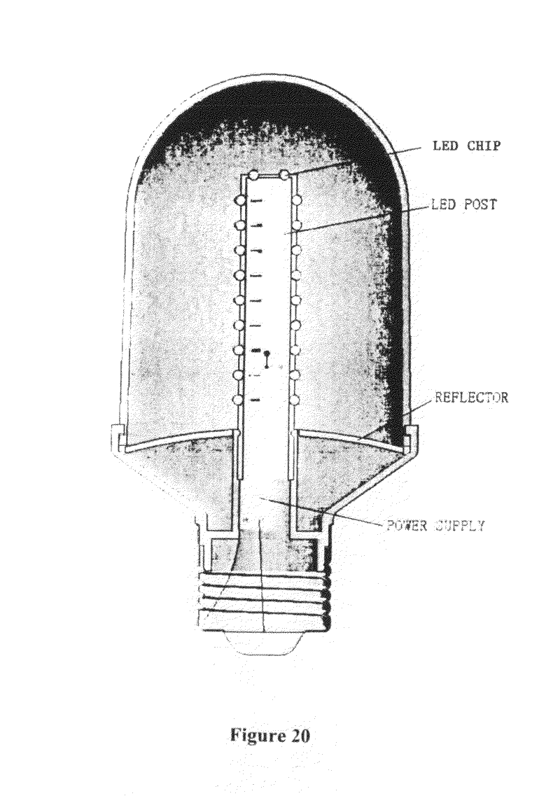

### DETAILED DESCRIPTION OF THE PREFERRED EMBODIMENT

One or more preferred embodiments of the invention will be described, but the embodiments are merely exemplary ways of implementing the invention and the invention is not limited to these exemplary embodiments.

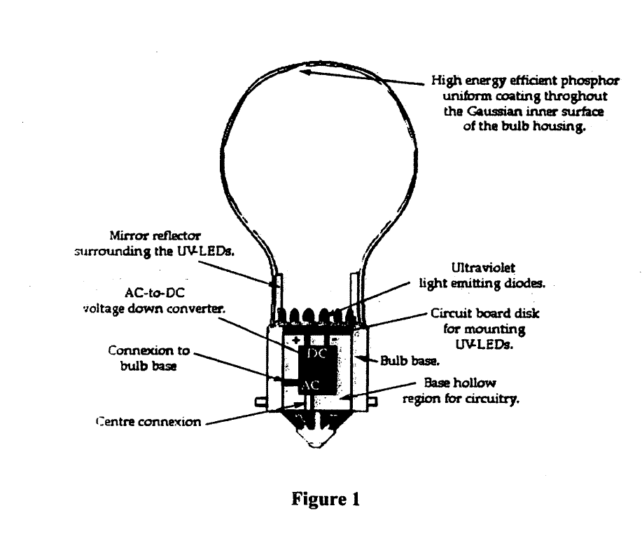

As shown in FIG. 1 one can incorporate currently manufactured, low cost, ultra-violet light emitting diodes of various UV wavelengths and situate the UV-LED and the voltage down converter(s) into a conventional light bulb design. This light bulb, which can either be made of glass or polycarbonate (non-breakable) will be coated with a thin film (uniform coating) of a high efficiency phosphor that can have a range of emitted colors for various applications and the shape of the light bulb can be conventional or any novel shape. Another advantage of this invention is that the bulb or other chosen novel shape does not need to be evacuated of ambient air.

Further if this bulb is designed to replace conventional fluorescent lights, in the form of long tubes or any other conventional shape, there is no need to pump into the tube or glass or polycarbonate shape any mercury vapour or Nobel gases such as Neon, Xenon, Argon, or Krypton. Also, unlike incandescent light bulbs which needs a vacuum, the lights according to the present invention do not need any vacuum.

As shown in FIG. 1 the UV-LED light can be mounted in the screw-in base, and the bulb or whatever shape is desired and chosen is coated with the high efficiency phosphor and the bulb shape acts as the final enclosure for the UV-LED and the voltage down converter. The voltage down converter converts the 110 VAC (US, and Pan American countries) or 240 VAC (UK, EU, Middle East, etc) to a level of 3.9 VDC @ 30 ma. Using the voltage down converter, which has an efficiency of about 90%, using high photon energy output phosphor the light output from this arrangement can save a huge amount of electrical energy versus light emission. The US version of the down converter converts 110 VAC to 3.6VDC @ 20 ma; so the power according to Ohm's Law is P=E×I (power equals voltage time current) or 3.6 volts times 0.020 amperes equals 0.072 watts. If the conversion circuitry is 90% efficient, then the actual power consumed is 0.0792 watts, still less than 1 watt to give the light output of a 100 watt incandescent light bulb. In the case for the UK or EU countries, the efficiency remains the same. There are also reflecting mirrors that assist in reflecting and re-directing the emitted UV light so as to propagate all throughout the enclosed volume coated with the phosphor compound layer.

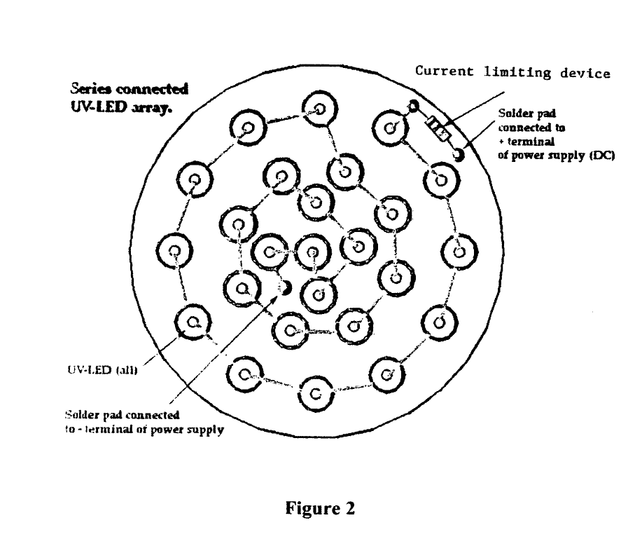

The light can have one UV-LED or a plurality of UV-LEDs forming an array as shown in FIG. 2. A series array would have a higher voltage and lower current while a parallel array of UV-LEDs would have a lower voltage and higher current. By Ohm's Law is realized that for an equal number of UV-LEDs in either a series or parallel array, the power consumed by each array is the same. With a parallel array, each diode would have its own current limiting element, such as a resistor or inductor.

The invention provides high-brightness blue and UV devices based on III-nitrides for the purpose of white-light LED sources. To develop efficient high-brightness white LED light sources, research has focused on fundamental studies of emission mechanisms in ZnS- and GaN-based wide-band gap compound semiconductors; improvement of epitaxial growth methods of multiple quantum wells (MQWs) and of external quantum efficiency of NUV LEDs; production of large substrates for homoepitaxial growth; development of multicolor, UV-excited phosphors that generate white light; and realization of illumination sources and fixtures using white LEDs.

Rare earth ions which are doped into solid host materials can give rise to sharp emissions in the visible spectral range. For example, Eu³⁺:Y₂O₃ is one of the most efficient red phosphors. Other rare earth ions have their emissions at different wavelengths. Yttrium aluminium borate (YAB) and Yttrium aluminium scandium borate are suitable hosts for rare-earth ions. In the quest for a material which shows rare earth emission in the visible range such that this emission stimulates a white colour perception we have produced dozens of doped YAB crystals containing different combinations and amounts of rare earth ions.

Among these many samples those systems which contained Tm³⁺ and Dy³⁺ simultaneously in the proper ratio were the only ones showing the desired effect.

The phosphor is represented by the general formula (Y1-x-yTmxDyy) Al3-zScz(BO3) (where 0<(x+y)_{—}1, 0_{— —}z_{—}3).

This phosphor, when irradiated by ultraviolet light having a wavelength of 350 nm or less, can produce white light having composed of the wavelengths 451, 455, 470, 474, 481, 485, 564, 567, 571, 574, 579 and several peaks in the range of ±5 nm around these wavelengths, having a colour temperature of approximately 4600-10000 degrees K.

The white emission results from luminescence of the rare earth ions alone and does not require the presence of mercury vapour emission bands. Further, the “white light LED” emits light beyond the warm white wavelength of 3,500 to 4,000 degrees Kelvin. The white light LED, through secondary quantum photon emission stimulated by ultraviolet LED light emission, gives a colour temperature that can be anywhere between 3,500 to 4,000 degrees K with a high yield of light intensity.

Unlike conventional super bright LEDs that use “high light output” efficient phosphors, which are coated in the well that holds in place, and completely surrounds, the LED semiconductor material used here takes and uses the same amount or a greater amount, depending on the application in question, and coats the inner Gaussian surface of the light enclosure with this phosphor, thus allowing for a uniform thin film of this phosphor embedded within a polycarbonate plastic injected moulded embodiment.

The potential applications for this phosphor material can include coatings for UV emitting gas discharge lamps, UV LEDs, plasma panels, or any other UV light emitting device. The white light generated by this phosphor is produced by luminescence only and can be generated by different kind of UV excitations. The substance is insoluble in water, acid or base and is heat resistant up to 1100° C.

Solid-state lighting is capable of saving $100 billion per year in electricity, with a corresponding savings of 200 billion tons of carbon emissions per year. This would be an enormous gain to society. Other marketing opportunities include flat panel displays, specialty lighting, biological sensors, quantum dot lasers, and novel floating gate memory structures.

An LED consists of several layers of semiconducting material. When a LED is operated with DC voltage light is generated in the active layer. The generated light is radiated directly or by reflections. In contrast to lamps, which emit a continuous spectrum, a LED emits light in a certain color. The color of the light depends on the used material. Two systems of material (AlInGaP and InGaN) are used in order to produce LED with a high luminance in all colors from blue to red and also in white (luminescence conversion). Therefore different voltages are necessary in order to operate the diode in conducting direction.

Typical super bright 5 mm UV-LEDs have color ranges from ultraviolet, blue to red, and infra-red. The method used to produce a complete visible spectrum color range of LEDs is to coat the well that holds and completely surrounds the small piece of semiconductor material, ranging in size from 0.1 mm to 1 mm. The cathode base and anode connection is electrically connected to the outside world by two stiff silver coated copper leads. The standard is that the anode lead is the longer lead and the cathode is the shorter lead for reference. An ultraviolet LED which has no phosphor coating along its well will emit UV light upon excitation. If phosphor is uniformly coated along the inner Gaussian surface of a typical incandescent style and size polycarbonate hollow bulb component, then the UV light will propagate outward from the LED well and will excite the phosphor atoms (coated along the inner Gaussian surface) to emit light, throughout the outer Gaussian surface, of a longer wavelength in accord with its quantum chemical characteristics. The phosphor acts as a wavelength shifting material or medium to shift the energy from the UV range to a longer wavelength which has a white color.

Unlike incandescent and fluorescent lamps, LEDs are not inherently white light sources. Instead, LEDs emit light in a very narrow range of wavelengths in the visible spectrum, resulting in nearly monochromatic light. This is why LEDs are so efficient for colored light applications such as traffic lights and exit signs. However, general light source, usually need white light. LED technology has the potential to produce high-quality white light with unprecedented energy efficiency.

White light can be achieved with LEDs in two main ways: 1) phosphor conversion, in which a blue or ultraviolet (UV) chip is coated with phosphor(s) to emit white light; and 2) RGB systems, in which light from multiple monochromatic LEDs (red, green, and blue) is mixed, resulting in white light.

The phosphor conversion approach is most commonly based on a blue LED. When combined with a yellow phosphor (usually cerium-doped yttrium aluminum garnet or YAG:Ce), the light will appear white to the human eye. A more recently developed approach uses an LED emitting in the near-UV region of the spectrum to excite multi-chromatic phosphors to generate white light.

The RGB approach produces white light by mixing the three primary colors red, green, and blue. Color quality of the resulting light can be enhanced by the addition of amber to “fill in” the yellow region of the spectrum.

Correlated color temperature (CCT) describes the relative color appearance of a white light source, indicating whether it appears more yellow/gold or more blue, in terms of the range of available shades of white. CCT is given in degrees Kelvin (the unit of absolute temperature) and refers to the appearance of a theoretical black body (visualize a chunk of metal) heated to high temperatures. As the black body gets hotter, it turns red, orange, yellow, white, and finally blue. The CCT of a light source is the temperature (in K) at which the heated theoretical black body matches the color of the light source in question. Incongruously, light sources with a higher CCT are said to be “cool” in appearance, while those with lower CCT are characterized as “warm.”

Color Rendering Index (CRI) indicates how well a light source renders colors, on a scale of 0-100, compared to a reference light source. The test procedure established by the International Commission on Illumination (CIE) involves measuring the extent to which a series of eight standardized color samples differ in appearance when illuminated under a given light source, relative to the reference source. The average “shift” in those eight color samples is reported as Ra or CRI.

In addition to the eight color samples used by convention, some lighting manufacturers report an “R9” score, which indicates how well the light source renders a saturated deep red color.

Consider now the arrangement of three ultraviolet emitting diodes that exist directly next to each other and each having a different wavelength. The three individual neighboring wavelengths in question are within a useable wavelength range of ultraviolet light to enhance each other. This is to be determined primarily by observation of each diode's narrow bandwidth and compare and match the resultants with a range of wavelengths having a viable and advantageous effect upon a phosphor compound in proximity of the diodes.

If there are three ultraviolet light emitting diodes whose wavelength are in relatively close proximity to each other in wavelength and actual physical distance, both Q and bandwidth can be increased as compared to any single UV-LED. Suppose there are two UV-LEDs of Q=20, and UV-LED of Q=10, then the overall bandwidth not only increases, but the total resultant amplitude of all three increases as well. Another feature of this approach is that diode (a) and diode (b) operate at a higher intensity, which means its excitation current is great than diode (m) that has the lower Q due to this methodology of staggering the wavelength and the power output of the individual diodes in comparison to each other. This technique allows for minimizing the current load, and gives more UV intensity over a wider bandwidth; some power is conserved. As this blend of photons of various energy levels and angular velocity strikes the ambient target phosphor atoms, they are excited and emit secondary emission at a lower angular velocity. If the phosphor coating is of an optimum thickness, the secondary emitted photons will pass through a polycarbonate hollow light enclosure and radiate through the phosphor layer to the enclosure's outer surface and in essence; provide an energy efficient and useful alternative light source to directly replace the incandescent light bulb, fluorescent tube type lights along with any and all variations of a theme.

The coefficient λa, is the wavelength of the one diode rated at a smaller value of wavelength, which is to say that its' frequency (angular velocity) is higher. This also means, from a quantum viewpoint, it emits photons with more photon energy. Planck's constant, h, (a coefficient of Plank's Law) was proposed in reference to the problem of black-body radiation. The underlying assumption to Planck's law of black body radiation was that the electromagnetic radiation emitted by a black body could be modeled as a set of harmonic oscillators with quantized energy of the form:

E=hν=hω/(2π)= [symbol] ω

E is the quantized energy of the photons of radiation having frequency (Hz) of ν (nu) or angular frequency (rad/s) of ω (omega).

The coefficient λ_{b}, is the wavelength of the one diode rated at a larger value of wavelength than λₐ, which is to say that its' frequency (angular velocity) is lower. This also means, from a quantum viewpoint, it emits photons with less photon energy in accordance with Plank's Law. The other term λₘ represents the middle wavelength (1/frequency), which is not used in the equation for solving the differential bandwidth Δ_{O} but rather used, since the resultant staggered bandwidth is flat over the majority of the resultant region, as a midway value representing a third Q (=10) value for peak intensity level of photon emission of diode (m).

The equation for finding the resultant value of Q and photon spectrum at the half power points (−3 dB) is:

Δ_{O}=λ_{b}−λₐ

the differential bandwidth at the −3 dB (half power) points.

Using this exampled value, which is an actual value used in the present invention; λₐ=395 nanometers in wavelength.

Further, this exampled value, which is an actual value used in the present invention; λ_{b}=450 nanometers in wavelength.

The middle exampled value, which is an actual value used in the present invention; λₘ=422 nanometers in wavelength. For practical purposes, the actual off the shelf available wavelength may not be produced but the nearest 3^{rd} UV-LED value of wavelength is to be considered.

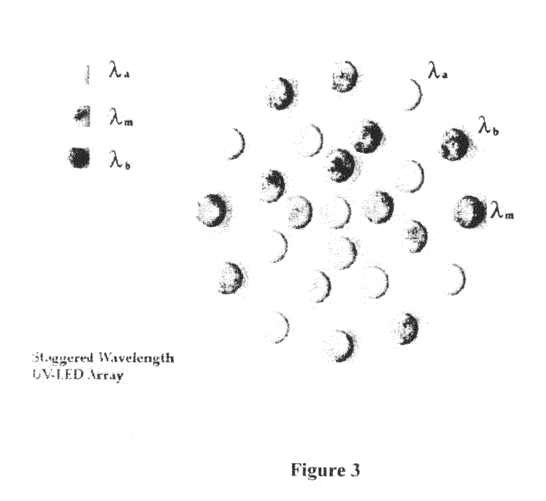

The staggered Gaussian distribution of photon emission can be realized in FIG. 3. The circular array of ultraviolet light emitting diodes in will have an overall photon emission pattern and spectral effect upon the thin filmed coating of high energy and high efficiency phosphor. The current fluorescent tube lights of various lengths can be replaced directly with a UV-LED equivalent of similar size and shape. The advantages are not only realized in watt-hour savings, but unlike present fluorescent lights which use toxic mercury (which is vaporized during operation) and the phosphor is coated on a glass tube, UV-LED lights according to the invention do not need any mercury, nor do they need to be constructed out of breakable glass. Rather polycarbonate can be used which can withstand tremendous punishment without any damage or breakage.

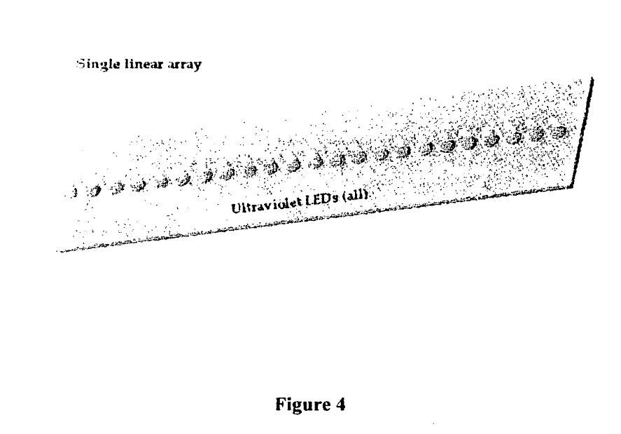

The UV-LED light can have a plurality of arrayed ultraviolet light emitting diodes as shown in FIGS. 4, 5 and 6. A single linear array of UV-LEDs, as shown in FIG. 4, can be utilized as the internal source of ultraviolet energy within a polycarbonate tube, covered with a uniform thin film coating of high efficiency phosphor throughout its inner Gaussian surface. Having an enclosure along with electrodes that are the same as conventional fluorescent light tubes of various tubular shapes, the light can be retrofitted as a direct replacement for the current fluorescent lights. In addition it requires no mercury/mercury vapor for its operation, and needs no hazardous glass tubes, which are (along with the mercury/mercury vapour) not bio-degradable. The methodology associated with applying phosphor in the glass tube is a gateway for this phosphor to become airborne and its toxic characteristics are realized as a potential environmental threat.

According to the present invention, the phosphor may be thermally encapsulated within the polycarbonate plastic during the process of an injection molding process.

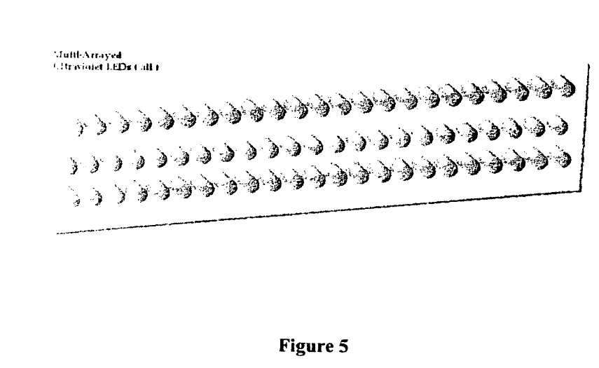

For applications that require larger light output, such as for commercial lighting sign systems, hospital operating room applications or any replacement for track type lighting systems (either incandescent or Halogen), and light tiles that can be installed on walls, ceilings, floors, etc.; multi-arrayed UV-LED banks, as shown in FIG. 5 can be used as direct replacement or “original idea” applications.

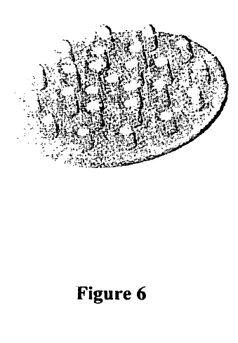

A linear array, linear multi-array, or a disk array, as shown in the image of FIG. 6, can be used for specialty lighting systems that are categorized as non-conventional or architectural design configurations.

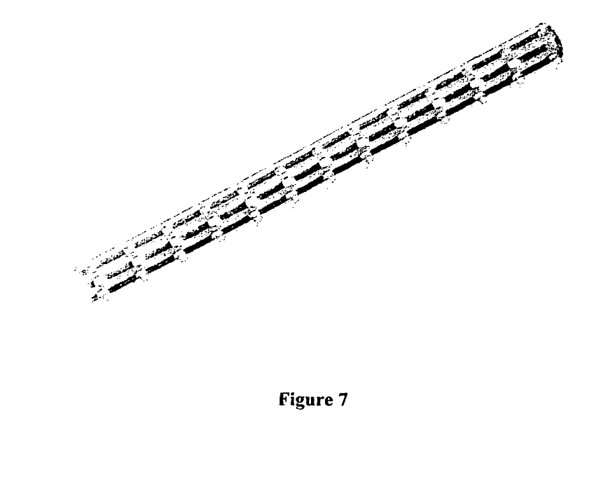

A lighting system can utilize ultraviolet light emitting diodes in a tubular array as shown in the computer rendering of FIG. 7. In FIG. 7 a circular cascaded linear array of ultraviolet light emitting diodes are connected in circular series and linear paralleled configuration (as illustrated). The grey regions are electrically conductive tinned copper strips (no-lead, RoHS compliant solder).

In the array of FIG. 7, the total resistive load is mathematically represented as:

Rₜ=1/{1/[R_{L1}+(R1ₛ₁+R2ₛ₁ . . . +Rnₛ₁)]+1/[R_{L2}+(R1ₛ₂+R2ₛ₂ . . . +Rnₛ₂)] . . . +1/[R_{Ln}+(Rnₛₙ+R(n+1)ₛₙ)]}
And power is realized as:

P=I²×Rₜ

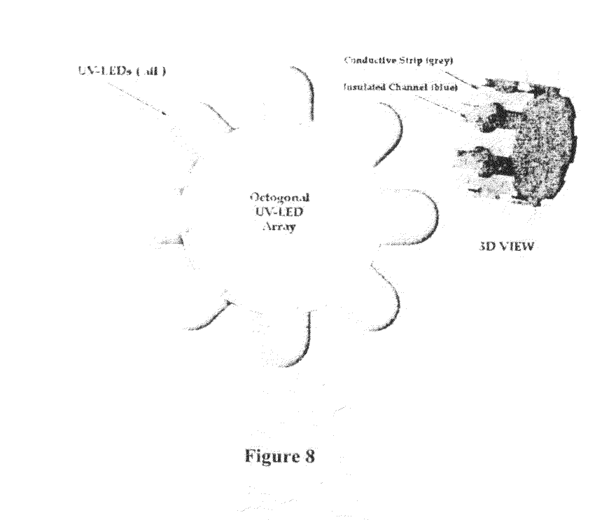

FIG. 8 is a cross section of the octagonal UV-LED array, which is connected in series with a current limiting resistor (not shown). By design, the series of eight UV-LEDs are connected in parallel and consequently the complete array is connected to a voltage down converter that produces a DC voltage from an AC mains source. The combination of UV wavelength can be varied and stagger tuned for colour control from warm to cool “white light.”

This UV-LED array of FIG. 7 and FIG. 8 will be placed in a polycarbonate hollow cylinder that has embedded within its composition; a high efficiency phosphor compound that will emit a broad band of “white light” when excited by ultraviolet light from the diodes. This will, through secondary quantum photon emission, produce a color range of white light from 3,500 to 4,100 nanometers in wavelength. This will produce a range of color temperature from warm to cool light, depending on application.

The substrate upon which the UV-LEDs are mounted in FIGS. 7 and 8 can be a flat substrate like a flexible circuit board material, having crease lines. The substrate can then be rolled up to form the shape shown in these or other Figures.

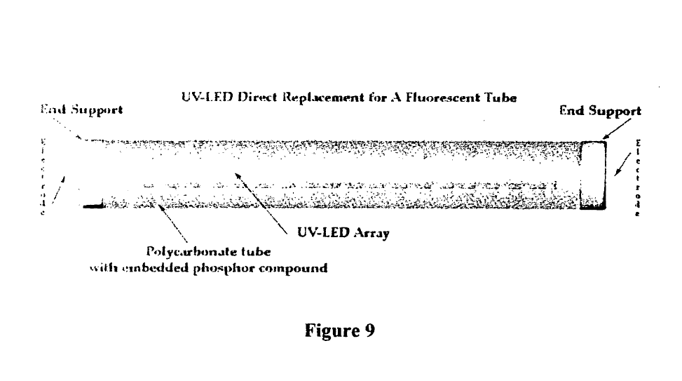

A typical “commercial direct replacement” for the fluorescent tube light is shown by a computer rendering in FIG. 9

FIG. 9 is another example of a light which can be produced in any size or shape as any current fluorescent tube type configuration.

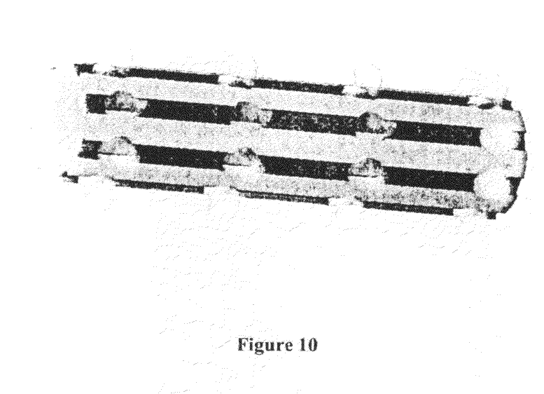

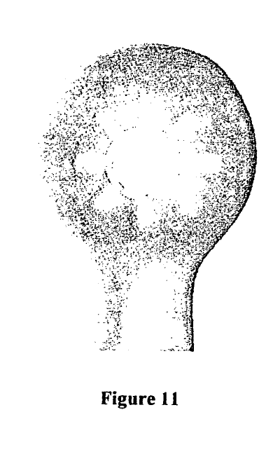

A vertical array as shown in the computer rendering of FIG. 10 is also a possible alternative configuration for vertical insertion into the hollow bulb structure. There is another configuration of using a single circular series array of UV-LEDs as shown in FIG. 11.

These figures generally show a central LED structure with a plurality of LEDs mounted on a post, a reflector below the LED structure, and the LED structure mounted in a base like that for a screw-in incandescent bulb. The base has a power supply for changing the 110 VAC input power to a lower level of DC power for driving the LEDS. The device has an outer shell which may be polycarbonate, either clear or semi-opaque. The semi-opaqueness may be due to wavelength shifting material on or in the shell material, from other coated or embedded material, or from having a textured surface during formation of the shell or from an etching or like process to produce a frosted appearance. An inner shell may be provided which can have any of the characteristics or features described above for the outer shell. The wavelength shifting material may be a coating on the inside or outside surface of one or both of the inner and outer shell, embedded into the shell material, or in any other way known to those skilled in the art.

Alternate approaches for phosphor implantation, based on an understanding the physics of luminescence at the nanoscale and methods of applying this knowledge to use “quantum based spheres,” which can be used as “quantum secondary emission” light sources can be used.

This approach of the present invention is based on encapsulating semiconductor quantum spheres (nanoparticles approximately one billionth of a meter in size) and engineering their surfaces so they efficiently emit visible light when excited by near-ultraviolet (UV) light-emitting diodes (LEDs). The quantum dots strongly absorb light in the near UV range and re-emit visible light that has its color determined by both their size and surface chemistry.

This nanophosphor sphere methodology and lighting system is quite different from prior art approaches based upon producing of blue, green, and red emitting semiconductor materials that requires careful mixing of the those primary colors to produce white illumination. Efficiently extracting all three colors in such a device requires costly chip designs, which likely cannot compete with conventional fluorescent lighting but can be attractive for more specialized lighting applications.

LEDs for solid-state lighting typically emit in the near UV to the blue part of the spectrum, around 380-450 nanometers. Conventional phosphors used in fluorescent lighting are not ideal for solid state lighting because they have poor absorption for these energies. So researchers worldwide have been investigating other chemical compounds for their suitability as phosphors for solid state lighting. However, they all seem to retrofit their research and development to applying the phosphors to the quantum well that holds the UV-LED chip in place, instead of encapsulating the phosphor, whether it be fine powders or the present invention's quantum nano-sphere approach.

The nanometer-size quantum spheres are synthesized in solvent containing soap-like molecules called surfactants as stabilizers. The small size of the quantum dots—much smaller than the wavelength of visible light—eliminates all light scattering and the associated optical losses. Optical backscattering losses using larger conventional phosphors reduce the package efficiency by as much as 50 percent.

Nanophosphors based upon quantum spheres have two significant advantages over the use of conventional bulk phosphor powders. First, while the optical properties of conventional bulk phosphor powders are determined solely by the phosphor's chemical composition, in quantum spheres the optical properties such as light absorbance are determined by the size of the sphere. Changing the size produces dramatic changes in color. The small sphere size also means that, typically, over 70 percent of the atoms are at surface sites so that chemical changes at these sites allow tuning of the light-emitting properties of the spheres, permitting the emission of multiple colors from a single size sphere.

This provides two additional ways to tune the optical properties in addition to chemical composition of the quantum sphere material itself. For the quantum spheres to be used for lighting, they need to be encapsulated, usually in epoxy or silicone. In doing this care must be taken not to alter the surface chemistry of the quantum spheres in transition from solvent to encapsulant.

A key technical issue in the encapsulation process must be understood. When altering the environment of the spheres from a solvent to an encapsulant, the quantum spheres could potentially “clump up” or agglomerate, causing the spheres to lose their light-emitting properties. By attaching the quantum spheres to the “backbone” of the encapsulating polymer they are close, but not touching. This allows for an increase in efficiency from 10-20 percent to an amazing 60 percent.

Quantum dot phosphors can be made from materials such as; nontoxic nanosize silicon or germanium semiconductors with light-emitting ions like manganese on the quantum sphere surface. Silicon, which is abundant, cheap, and non-toxic, is an ideal an ideal material to be considered. The quantum spheres can be fabricated easily at very low production cost.

Stokes shift is the difference (in wavelength or frequency units) between positions of the band maxima of the absorption and luminescence spectra (or fluorescence) of the same electronic transition. When a molecule or atom absorbs light, it enters an excited electronic state. The Stokes shift occurs because the molecule loses a small amount of the absorbed energy before re-releasing the rest of the energy as luminescence or fluorescence (the so-called Stokes fluorescence), depending on the time between the absorption and the reemission. This energy is often lost as thermal energy.

Stokes fluorescence is the reemission of longer wavelength (lower frequency) photons (energy) by a molecule that has absorbed photons of shorter wavelengths (higher frequency). Both absorption and radiation (emission) of energy are unique characteristics of a particular molecule (structure) during the fluorescence process. Light is absorbed by molecules in about 10⁻¹⁵ seconds which causes electrons to become excited to a higher electronic state. The electrons remain in the excited state for about 10⁻⁸ seconds then, assuming all of the excess energy is not lost by collisions with other molecules, the electron returns to the ground state. Energy is emitted during the electrons' return to their ground state. Emitted light always has a longer wavelength than the absorbed light due to limited energy loss by the molecule prior to emission.

A quantum sphere or rod is a semiconductor nanostructure that confines the motion of conduction band electrons, valence band holes, or excitons (pairs of conduction band electrons and valence band holes) in all three spatial directions. The confinement can be due to electrostatic potentials (generated by external electrodes, doping, strain, impurities), due to the presence of an interface between different semiconductor materials (e.g. in the case of self-assembled quantum dots), due to the presence of the semiconductor surface (e.g. in the case of a semiconductor nanocrystal), or due to a combination of these. A quantum dot or rod has a discrete quantized energy spectrum. The corresponding wave functions are spatially localized within the quantum dot, but extend over many periods of the crystal lattice. A quantum dot contains a small finite number (of the order of 1-100) of conduction band electrons, valence band holes, or excitons, i.e., a finite number of elementary electric charges.

Small quantum dots as well as quantum rods, such as colloidal semiconductor nanocrystals, can be as small as 2 to 10 nanometers or 20-100 for rods, corresponding to 10 to 50 atoms in diameter and a total of 100 to 100,000 atoms within the quantum dot volume. Self-assembled quantum dots are typically between 10 and 50 nanometers in size. Quantum dots defined by lithographically patterned gate electrodes, or by etching on two-dimensional electron gases in semiconductor heterostructures can have lateral dimensions exceeding 100 nanometers. At 10 nanometers in diameter, nearly 3 million quantum dots could be lined up end to end and fit within, the width of a human thumb.

Quantum dots can be contrasted to other semiconductor nanostructures: 1) quantum wires, which confine the motion of electrons or holes in two spatial directions and allow free propagation in the third. 2) quantum wells, which confine the motion of electrons or holes in one direction and allow free propagation in two directions.

Quantum dots containing electrons can also be compared to atoms: both have a discrete energy spectrum and bind a small number of electrons. In contrast to atoms, the confinement potential in quantum dots does not necessarily show spherical symmetry. In addition, the confined electrons do not move in free space, but in the semiconductor host crystal. The quantum dot host material, in particular its band structure, does therefore play an important role for all quantum dot properties. Typical energy scales, for example, are of the order of ten electron volts in atoms, but only 1 millielectron volt in quantum dots. Quantum dots with a nearly spherical symmetry, or flat quantum dots with nearly cylindrical symmetry can show shell filling according to the equivalent of Hund's rules for atoms. Such dots are sometimes called “artificial atoms”. In contrast to atoms, the energy spectrum of a quantum dot can be engineered by controlling the geometrical size, shape, and the strength of the confinement potential. Also in contrast to atoms it is relatively easy to connect quantum dots by tunnel barriers to conducting leads, which allows the application of the techniques of tunneling spectroscopy for their investigation.

Like in atoms, the energy levels of small quantum dots can be probed by optical spectroscopy techniques. In quantum dots that confine electrons and holes, the inter-band absorption edge is blue shifted due to the confinement compared to the bulk material of the host semiconductor material. As a consequence, quantum dots of the same material, but with different sizes, can emit light of different colors.

Quantum dots are particularly significant for optical applications due to their theoretically high quantum yield. In electronic applications they have been proven to operate like a single-electron transistor and show the Coulomb blockade effect. Quantum dots have also been suggested as implementations of qubits for quantum information processing.

One of the optical features of small excitonic quantum dots immediately noticeable to the unaided eye is coloration. While the material which makes up a quantum dot defines its intrinsic energy signature, more significant in terms of coloration is the size. The case is the larger the dot, the redder (the more towards the red end of the spectrum) the fluorescence. The smaller the dot, the bluer (the more towards the blue end) it is. The coloration is directly related to the energy levels of the quantum dot. Quantitatively speaking, the bandgap energy that determines the energy (and hence color) of the fluoresced light is inversely proportional to the square of the size of the quantum dot. Larger quantum dots have more energy levels which are more closely spaced. This allows the quantum dot to absorb photons containing less energy, i.e. those closer to the red end of the spectrum. Recent articles in nanotechnology and other journals have begun to suggest that the shape of the quantum dot may well also be a factor in the colorization, but as yet not enough information has become available.

The ability to tune the size of quantum dots is advantageous for many applications. For instance, larger quantum dots, have spectra shifted towards the red compared to smaller dots, and exhibit less pronounced quantum properties. Conversely the smaller particles allow one to take advantage of quantum properties.

It should be understood that the wavelength shifting medium according to the invention can be any single or any combination of two or more of the materials disclosed herein, such as phosphor and quantum dots. The medium may also include flakes as reflectors.

A thin layer of gold would provide a warm glow or color whether the light was powered on or not. The flakes could be any desired size, including down to nanometer size.

The invention also provides a photon energy conversion device in the form of a first electrode layer being generally transmissive to photon energy, a second electrode layer, and a layer of photon energy conversion material in the form of quantum dots disposed between the first layer and second layer. The electrode materials may include metals, such as copper, gold and/or aluminum.

While several embodiments have been disclosed, the invention is not limited to these embodiments and is defined only by way of the following claims.

I claim:

1. A light source comprising:
a photon emission source in the wavelength range of ultraviolet to near ultraviolet (less than about 350 nm); and
a wavelength shifting medium which receives emitted photons and emits lower frequency energy in the wavelength range of about 400-700 nm, and in a substantially uniform, unfocussed, omni directional radiation pattern.

2. The light source according to claim 1, wherein said wavelength shifting medium comprises quantum material embedded within an oxygen free encapsulation.

3. The light source according to claim 2, wherein the quantum material comprises at least one of quantum dots and quantum rods.

4. The light source of claim 1, where the wavelength shifting medium comprises high luminosity phosphor material.

5. The light source of claim 4, wherein the phosphor material is embedded within an oxygen free encapsulation.

6. The light source of claim 1, wherein the photon emission source and wavelength shifting medium are mounted on a flexible substrate.

7. The light source of claim 1, wherein the wavelength shifting medium comprises quantum material and phosphor material.

8. The light source of claim 3, wherein the quantum material is formed in at least one uniform layer.

9. The light source of claim 8, wherein the quantum material is formed in a plurality of layers.

10. The light source of claim 1, wherein the wavelength shifting material is spaced from the photon emission source.

11. The light source of claim 1, wherein the photon emission source comprises at least one light emitting diode (LED).

12. The light source of claim 11, wherein the photon emission source comprises a plurality of light emitting diodes (LEDs)

13. The light source of claim 12, wherein at least some of the LEDs are connected in series.

14. The light source of claim 12, wherein at least some of the LEDs are connected in parallel.

15. The light source of claim 1, wherein the light source is in the shape of a standard incandescent bulb adapted to be used in place of a standard incandescent bulb.

16. The light source of claim 15, wherein the light source is in comprises a bulb shell of the type used for incandescent light bulbs, wherein the photon emission source is disposed near the based inside the shell and herein the wavelength shifting medium is disposed as part of the bulb shell.

17. The light source of claim 15, wherein, the bulb has a base consisting of one of a screw shape or a bayonet shape.

18. The light source of claim 1, wherein the wavelength shifting medium comprises a coating on the bulb shell.

19. The light source of claim 1, wherein the wavelength shifting medium is integral with the bulb shell.

20. The light source of claim 1, wherein the light source is in the shape of a fluorescent light bulb having a shape selected from the group consisting of a tube, a circle and a compact florescent light (CFL) spiral.

21. The light source of claim 1, wherein the wavelength shifting medium emits light which appears to be white light to a human.

22. The light source of claim 1, wherein the wavelength shifting medium emits light which has a selected wavelength corresponding to a single color.

23. The light source of claim 1, further including a reflector.

24. The light source of claim 20, wherein the light source is in the shape of a tube, and wherein the photon emission source is a plurality of LEDs arranged in circular fashion throughout the length of the tube, and wherein the wavelength shifting material comprises a polycarbonate tube with embedded phosphor compound.

25. The light source of claim 16 wherein the light source further comprises a mirror reflector encircling a circuit board at the base of the bulb for carrying a plurality of LEDs, a mirror reflector at the base of the bulb encircling the circuit board, and a substantially uniform phosphor coating on substantially the entire surface of the bulb.

26. The light source of claim 1, wherein the wavelength shifting material comprises rare earth ions doped into solid host materials to provide light emissions in the wavelength range of about 400-700 nm.

27. The light source of claim 26, wherein the wavelength shifting material comprises Tm³⁺ and Dy³⁸.

28. The light source of claim 1, wherein photon emission source comprises at least one LED formed from one of AlGaP and InGaN.

29. The light source of claim 1, wherein the wavelength shifting material comprises nanophosphors.

30. A photon energy conversion device in the form of a first electrode layer being generally transmissive to photon energy, a second electrode layer, and a layer of photon energy conversion material in the form of quantum dots disposed between the first layer and second layer.
